(19) United States
(12) Patent Application Publication
(10) Pub. No.: US 2023/0053478 A1
(43) Pub. Date: Feb. 23, 2023

(54) DISPLAY MODULE

(71) Applicant: Acer Incorporated, New Taipei City (TW)

(72) Inventors: Chao-Di SHEN, New Taipei City (TW); Po-Yi LEE, New Taipei City (TW); Yu-Wen LIN, New Taipei City (TW); Yen-Chieh CHIU, New Taipei City (TW); Huei-Ting CHUANG, New Taipei City (TW); Hung-Chi CHEN, New Taipei City (TW); Shun-Bin CHEN, New Taipei City (TW)

(21) Appl. No.: 17/697,094

(22) Filed: Mar. 17, 2022

(30) Foreign Application Priority Data
Aug. 17, 2021 (TW) 110209666

(51) Int. Cl. H05K 5/00

(52) U.S. Cl. CPC H05K 5/0013; H05K 5/0017

(57) ABSTRACT

A display module is provided, including a housing, a display unit disposed in the housing, and a hollow frame. The housing includes a plate, a sidewall, and a first hook, wherein the sidewall and the hook protrude from the plate. The frame includes a second hook close to the side of the frame and extending toward the housing. When the frame is joined to the housing, the second hook is hooked to the first hook.

### CROSS REFERENCE TO RELATED APPLICATIONS

This application claims priority of Taiwan Patent Application Ser. No. 110209666, filed on Aug. 17, 2021, the entirety of which is incorporated by reference herein.

### BACKGROUND OF THE INVENTION

### Field of the Invention

The application relates in general to a display module, and in particular, to a display module that has a joining mechanism.

### Description of the Related Art

In conventional laptop computers, since the camera module is located above the screen, the frame surrounding the screen usually has a considerable width. As a result, it is hard to reduce the overall size of laptop computers. Additionally, to manufacture a laptop computer with a thin frame and a high screen-to-body ratio, the plastic hooks used inside the display of conventional laptop computers need to be redesigned. Addressing the aforementioned problems has become a challenge.

### BRIEF SUMMARY OF INVENTION

In view of the aforementioned problems, the object of the invention is to provide a display module that includes a housing, a display unit, and a hollow frame. The housing has a plate, a sidewall, and a first joining mechanism, wherein the sidewall and the first joining mechanism protrude from the plate, and the first joining mechanism has a first hook. The display unit is disposed in the housing, and the hollow frame has a second joining mechanism.

In some embodiments, the second joining mechanism has a second hook located close to the side of the frame and extending toward the housing, wherein when the frame is joined to the housing, the second hook is hooked to the first hook to prevent the frame from being separated from the housing.

In some embodiments, the first and second hooks have a length running parallel to the side of the frame, and the first and second hooks have a width that runs perpendicular to the side of the frame, wherein the width is shorter than the length.

In some embodiments, the housing has a first protrusion protruding from the plate, and the frame has a second protrusion positioned and restricted between the first protrusion and the sidewall of the housing when the frame is joined to the housing.

In some embodiments, the first joining mechanism has two first hooks, and the second joining mechanism has two second hooks hooked to the first hooks to prevent the frame from being separated from the housing.

In some embodiments, the first and second hooks are arranged in a direction parallel to the side of the frame.

In some embodiments, the tails of the first hooks extend outwardly with respect to the first joining mechanism.

In some embodiments, the tails of the second hooks extend inwardly with respect to the second joining mechanism.

In some embodiments, the first joining mechanism also has a connecting portion connected between the two first hooks.

In some embodiments, the first joining mechanism also has a hole surrounded by the connecting portion, the two first hooks, and the plate of the housing.

In some embodiments, the first joining mechanism also has a curved concave surface formed between the two first hooks.

In some embodiments, the first hook of the first joining mechanism and the second hook of the second joining mechanism are both in the shape of a golf driver head.

### BRIEF DESCRIPTION OF DRAWINGS

The invention can be more fully understood by reading the subsequent detailed description and examples with references made to the accompanying drawings, wherein:

FIG. 1 shows a perspective diagram of an electronic device 100 in accordance of an embodiment of the invention.

FIG. 2 shows an exploded diagram of the display module 20 in FIG. 1.

FIG. 3 shows another exploded diagram of the display module 20 in FIG. 1.

FIG. 4 shows a perspective diagram of the housing 21 of the display module 20 in accordance of an embodiment of the invention.

FIG. 5 shows a partial enlarged view of the housing 21 in FIG. 4.

FIG. 6 shows a perspective diagram of the frame 22 of the display module 20 in accordance of an embodiment of the invention.

FIG. 7 shows a partial enlarged view of the frame 22 in FIG. 6.

FIG. 8 shows a cross-sectional view of the display module 20 after assembly.

FIG. 9 shows an enlarged cross-sectional view of the display module 20 in FIG. 8.

FIG. 10 shows an enlarged cross-sectional view of the housing 21 and the frame 22 when the first and second hooks J11 and J21 are joined together.

FIG. 11 shows a partial cross-sectional view of the housing 21 and the frame 22 when connected to each other.

FIG. 12 shows the first and second hooks J11 and J21 having a width of d.

FIG. 13 shows a perspective diagram of the first and second joining mechanisms J1 and J2 in accordance of another embodiment of the invention.

FIG. 14 shows a perspective diagram of the first and second joining mechanisms J1 and J2 in accordance of another embodiment of the invention.

FIG. 15 shows a perspective diagram of the first and second hooks J11 and J21 joined together.

FIG. 16 shows a cross-sectional view of the housing 21 and the frame 22 when the first and second joining mechanisms J1 and J2 are joined together.

### DETAILED DESCRIPTION OF INVENTION

The making and using of the embodiments of the display module are discussed in detail below. It should be appreciated, however, that the embodiments provide many applicable inventive concepts that can be embodied in a wide variety of specific contexts. The specific embodiments discussed are merely illustrative of specific ways to make and use the embodiments, and do not limit the scope of the disclosure.

Unless defined otherwise, all technical and scientific terms used herein have the same meaning as commonly understood by one of ordinary skill in the art to which this invention belongs. It should be appreciated that each term, which is defined in a commonly used dictionary, should be interpreted as having a meaning conforming to the relative skills and the background or the context of the present disclosure, and should not be interpreted in an idealized or overly formal manner unless defined otherwise.

In the following detailed description of the preferred embodiments, reference is made to the accompanying drawings, and in which specific embodiments of which the invention may be practiced are shown by way of illustration. In this regard, directional terminology, such as “top,” “bottom,” “left,” “right,” “front,” “back,” etc., is used with reference to the orientation of the figures being described. The components of the present invention can be positioned in a number of different orientations. As such, the directional terminology is used for the purposes of illustration and is in no way limiting.

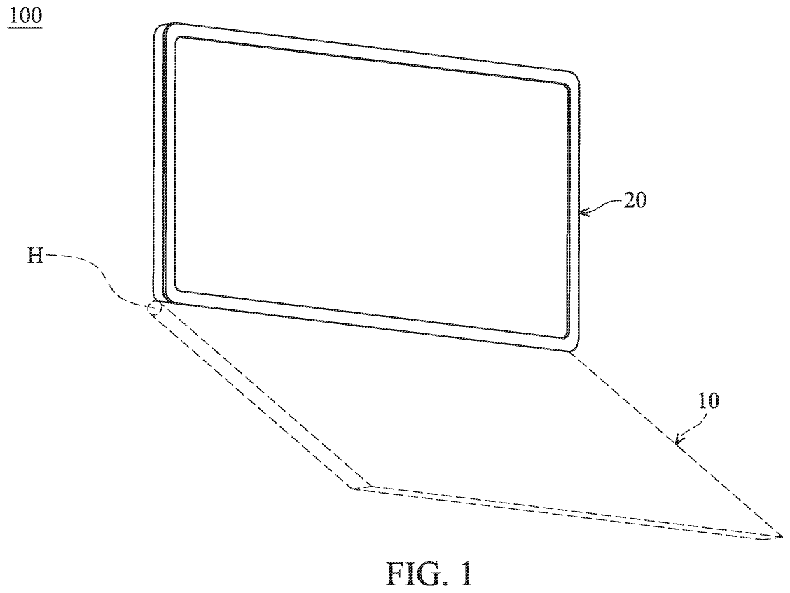

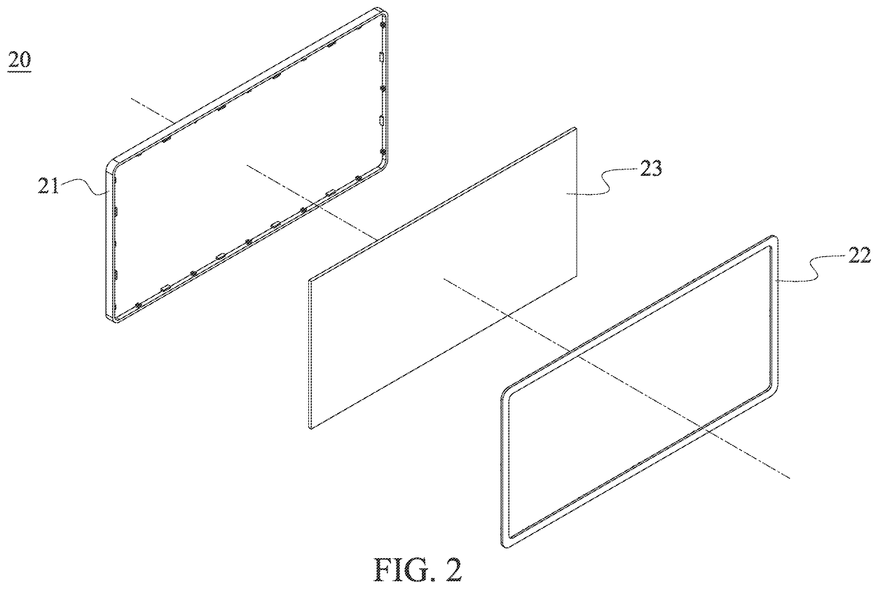

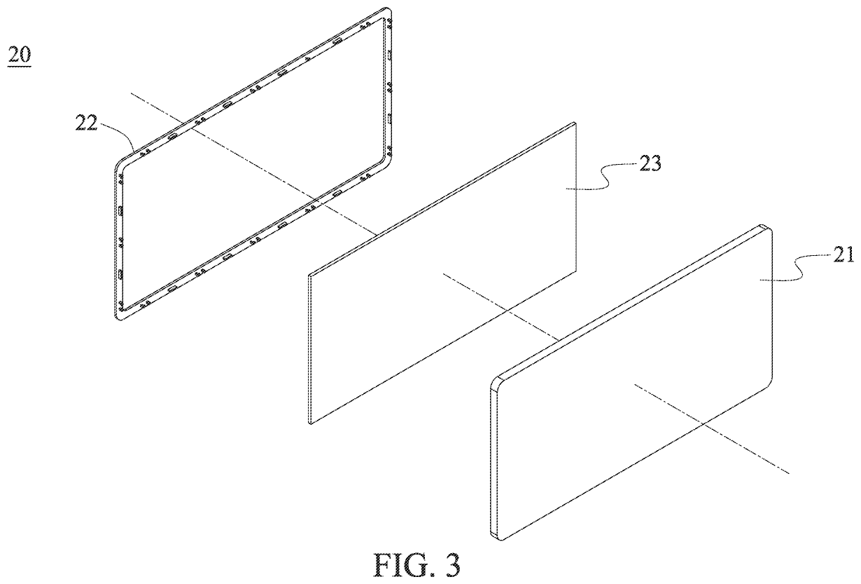

FIG. 1 shows a perspective diagram of an electronic device 100 in accordance of an embodiment of the invention. FIG. 2 shows an exploded diagram of the display module 20 in FIG. 1. FIG. 3 shows another exploded diagram of the display module 20 in FIG. 1.

Referring to FIGS. 1-3, the electronic device 100 in this embodiment may be a laptop computer that has an input module 10 and a display module 20 pivotally connected to each other via a hinge H. Therefore, the display module 20 can rotate relative to the input module 10.

In this embodiment, the display module 20 has a rectangular housing 21, a hollow frame 22, and a display unit 23, wherein the display unit 23 may include an LCD or OLED panel. During assembly of the display module 20, the display unit 23 is disposed in the housing 21, and the frame 22 is then secured to the housing 21, so that the display unit 23 can be affixed at the center of the display module 20.

In some embodiments, a keyboard (e.g. QWERTY keyboard) and/or a touch pad may be provided on the surface of the input module 10. It should be noted that the keyboard and/or the touch pad can be used as a user input interface, whereby the users can easily use the electronic device 100. After the display module 20 is unfolded relative to the input module 10, the users can input the instructions or control the mouse cursor on the screen of the display module 20.

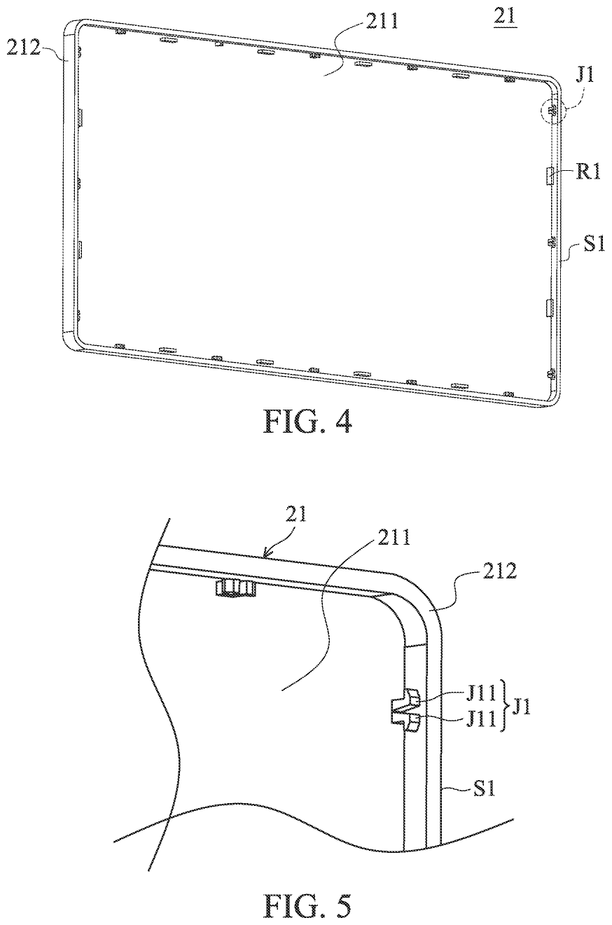

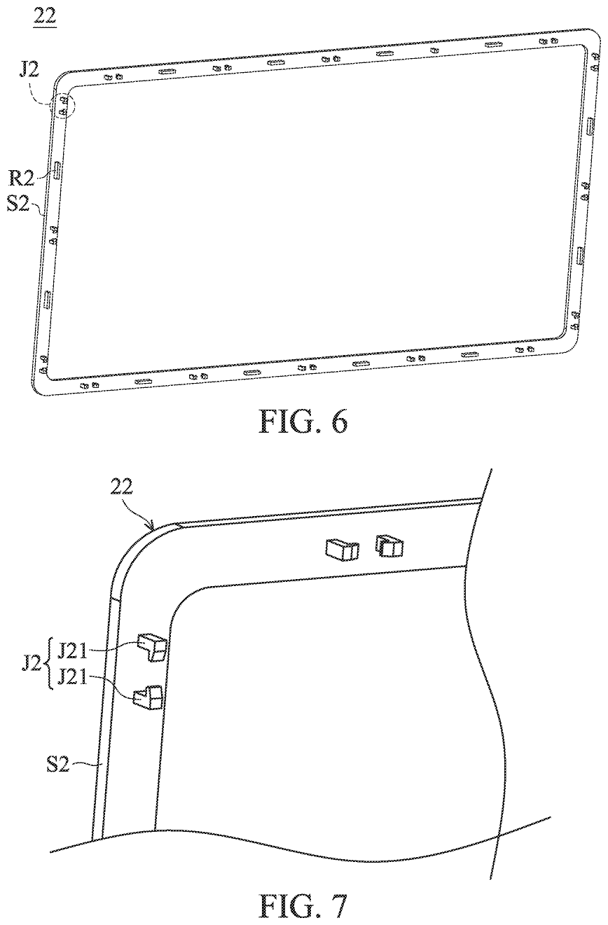

FIG. 4 shows a perspective diagram of the housing 21 of the display module 20 in accordance of an embodiment of the invention. FIG. 5 shows a partial enlarged view of the housing 21 in FIG. 4. FIG. 6 shows a perspective diagram of the frame 22 of the display module 20 in accordance of an embodiment of the invention. FIG. 7 shows a partial enlarged view of the frame 22 in FIG. 6.

As shown in FIGS. 4 and 5, the housing 21 of the display module 20 has a plate 211 and a rectangular sidewall 212 protruding from the plate 211. Specifically, at least a first joining mechanism J1 is formed on the plate 211 and located adjacent to a side S1 of the housing 21.

It can be seen in FIG. 5 that the first joining mechanism J1 includes two symmetrical first hooks J11 that are spaced apart from each other, and the tails of the first hooks J11 extend outwardly with respect to the first joining mechanism J1.

Moreover, as shown in FIGS. 6 and 7, the frame 22 of the display module 20 has a substantially rectangular hollow structure. At least a second joining mechanism J2 is formed on the frame 22 and located adjacent to a side S2 of the frame 22. In this embodiment, the second joining mechanism J2 extends toward the housing 21, and the side S2 of the frame 22 is located corresponding to the side S1 of the plate 211.

It can be seen in FIG. 7 that the second joining mechanism J2 includes two symmetrical second hooks J21 that are spaced apart from each other, and the tails of the second hooks J21 extend inwardly with respect to the second joining mechanism J2. During assembly of the housing 21 and the frame 22, the second hooks J21 are hooked to the first hooks J11, so that the frame 22 and the housing 21 are firmly secured to each other.

In this embodiment, the frame 22 and the housing 21 comprise plastic material. The first joining mechanism J1 may be integrally formed with the housing 21 in one piece by plastic injection molding. Similarly, the second joining mechanism J2 may be integrally formed with the frame 22 in one piece by plastic injection molding.

Additionally, referring to FIGS. 4 and 6, at least a first protrusion R1 is formed on the plate 211 of the housing 21, and at least a second protrusion R2 is formed on the frame 22. When the frame 22 and the housing 21 are joined together, the second protrusion R2 is positioned and restricted between the first protrusion R1 and the sidewall 212 of the housing 21. Therefore, the displacement of the frame 22 relative to the housing 21 in a direction perpendicular to the sides S1 and S2 can be avoided.

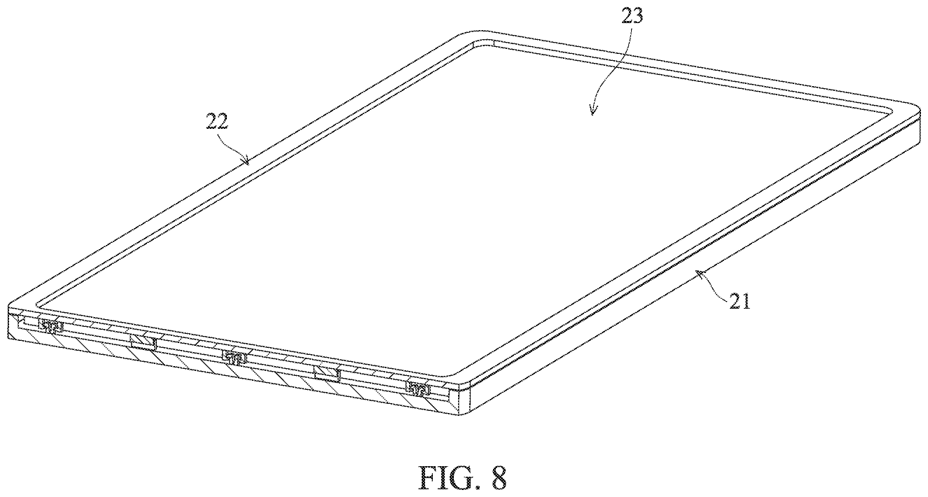

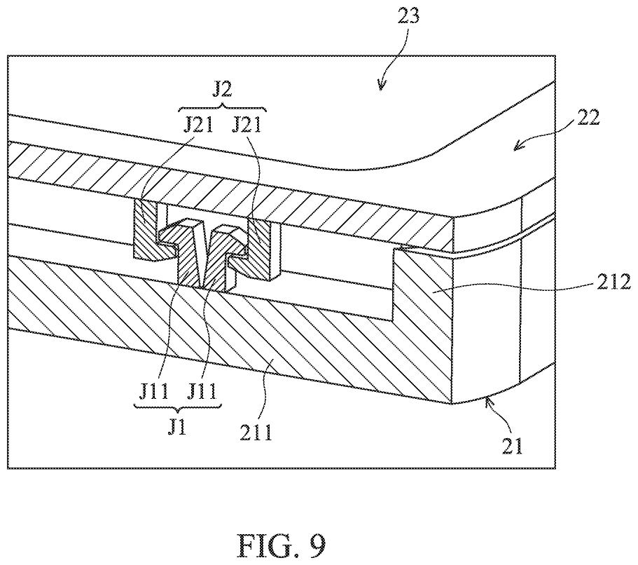

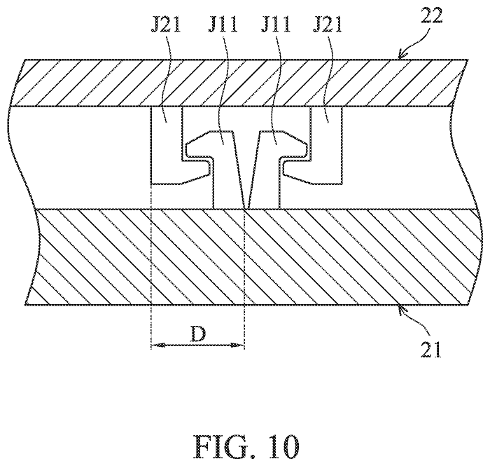

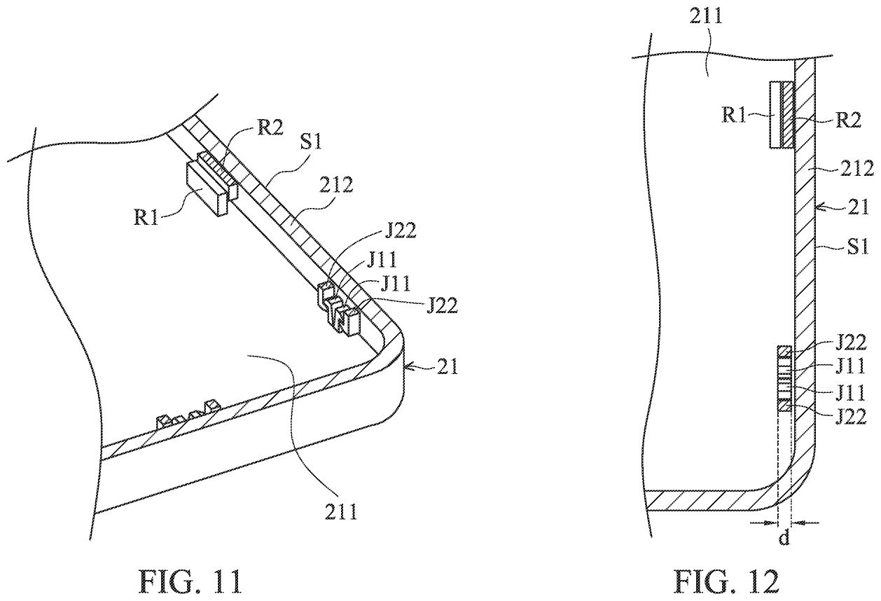

FIG. 8 shows a cross-sectional view of the display module 20 after assembly. FIG. 9 shows an enlarged cross-sectional view of the display module 20 in FIG. 8. FIG. 10 shows an enlarged cross-sectional view of the housing 21 and the frame 22 when the first and second hooks J11 and J21 are joined together. FIG. 11 shows a partial cross-sectional view of the housing 21 and the frame 22 when connected to each other. FIG. 12 shows the first and second hooks J11 and J21 having a width of d.

Referring to FIGS. 8-12, when the housing 21 and the frame 22 are assembled to each other, the second hooks J21 of the second joining mechanism J2 are hooked to the first hooks J11 from the outer side of the first joining mechanism J1, whereby the frame 22 can be prevented from being separated from the housing 21. As shown in FIG. 10, the first hook J11 and the second hook J21 hooked thereon have a length D in a direction parallel to the sides S1 and S2. Moreover, the first and second hooks J11 and J21 have a width of d perpendicular to the sides S1 and S2 (FIG. 12), wherein the width d is shorter than the length D.

In this embodiment, the first and second joining mechanisms J1 and J2 are located close to the side S1 of the housing 21 and the side S2 of the frame 22, and the first and second hooks J11 and J21 of the first and second joining mechanisms J1 and J2 are arranged along the he sides S1 and S2. Hence, the thickness of the frame 22 can be greatly reduced to achieve thin frame of the display module 20. As a result, the display unit 23 can also be enlarged to increase the screen-to-body ratio of the display module 20.

Still referring to FIGS. 11 and 12, when the housing 21 and the frame 22 are assembled to each other, the second protrusion R2 is positioned and restricted between the first protrusion R1 and the sidewall 212 of the housing 21. Therefore, the displacement of the frame 22 relative to the housing 21 in a direction perpendicular to the sides S1 and S2 can be avoided after assembly of the display module 20.

In some embodiments, the first protrusion R1 may be positioned and restricted between the second protrusion R2 and the sidewall 212 of the housing 21, so that the displacement of the frame 22 relative to the housing 21 in a direction perpendicular to the sides S1 and S2 can be avoided.

FIG. 13 shows a perspective diagram of the first and second joining mechanisms J1 and J2 in accordance of another embodiment of the invention. FIG. 13 is different from the embodiment of FIGS. 1-12 in that the first joining mechanism J1 also has a connecting portion J21 connected between the two first hooks J11, and a hole J10 is surrounded by the connecting portion J21, the two first hooks J11, and the plate 211 of the housing 21.

In this embodiment, the two first hooks J11 are connected to each other via the connecting portion J21, thereby enhancing the structural strength of the first joining mechanism J1 and preventing the first joining mechanism J1 from being damaged when impacted by external force.

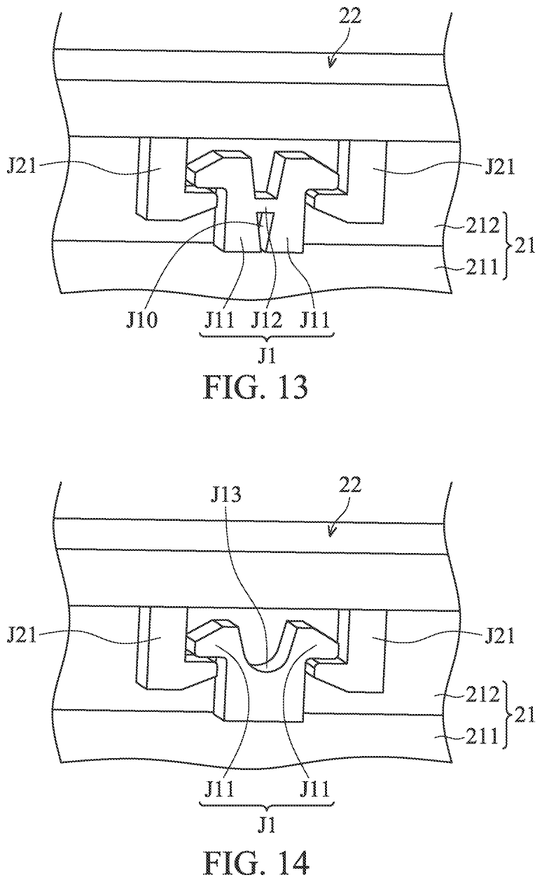

FIG. 14 shows a perspective diagram of the first and second joining mechanisms J1 and J2 in accordance of another embodiment of the invention. FIG. 14 is different from the embodiment of FIGS. 1-12 in that the two first hooks J11 of the first joining mechanism J1 are directly connected to each other, so as to enhance the structural strength of the first joining mechanism J1 and prevent the first joining mechanism J1 from being damaged when impacted by external force.

Referring to FIG. 14, a curved concave surface J13 is formed between the two first hooks J11, whereby stress concentration on the surface of the first joining mechanism J1 can be efficiently prevented.

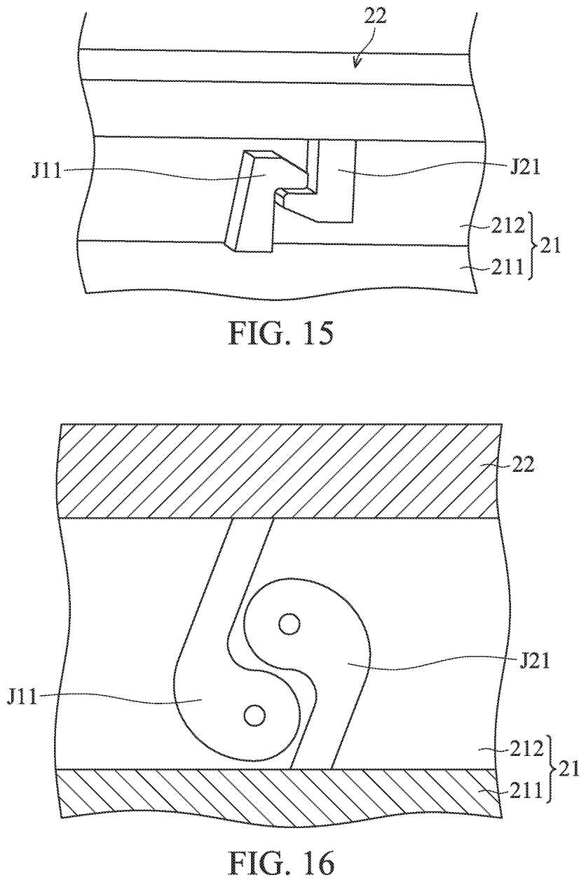

FIG. 15 shows a perspective diagram of the first and second hooks J11 and J21 joined together. FIG. 15 is different from the embodiment of FIGS. 1-12 in that the first joining mechanism J1 has only one first hook J11, and the second joining mechanism J2 has only one second hook J21.

It should be noted that the when the housing 21 and the frame 22 are assembled to each other, the second hook J21 is hooked to the first hook J11, whereby the frame 22 can be prevented from being separated from the housing 21. As the first joining mechanism J1 has only one first hook J11, and the second joining mechanism J2 has only one second hook J21, more space inside the housing 21 can be provided, so as to facilitate miniaturization and high screen-to-body ration of the display module 20.

FIG. 16 shows a cross-sectional view of the housing 21 and the frame 22 when the first and second joining mechanisms J1 and J2 are joined together. FIG. 16 is different from the embodiment of FIG. 15 in that the first hook J11 of the first joining mechanism J1 and the second hook J21 of the second joining mechanism J2 are both shaped like a golf driver head, and the first and second hooks J11 and J21 form a pattern of Tai-Chi when joined together.

Although some embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, compositions of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps. Moreover, the scope of the appended claims should be accorded the broadest interpretation so as to encompass all such modifications and similar arrangements.

While the invention has been described by way of example and in terms of preferred embodiment, it should be understood that the invention is not limited thereto. On the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. A display module, comprising:
a housing, having a plate, a sidewall, and a first joining mechanism, wherein the sidewall and the first joining mechanism protrude from the plate, and the first joining mechanism has a first hook;
a display unit, disposed in the housing; and
a hollow frame, having a second joining mechanism, wherein the second joining mechanism has a second hook located close to a side of the frame and extending toward the housing, wherein when the frame is joined to the housing, the second hook is hooked to the first hook to prevent the frame from being separated from the housing;
wherein the first and second hooks have a length parallel to the side of the frame, and the first and second hooks have a width perpendicular to the side of the frame, wherein the width is shorter than the length.

2. The display module as claimed in claim 1, wherein the housing has a first protrusion protruding from the plate, and the frame has a second protrusion restricted between the first protrusion and the sidewall of the housing when the frame is joined to the housing.

3. The display module as claimed in claim 1, wherein the first joining mechanism has two first hooks, and the second joining mechanism has two second hooks hooked to the first hooks to prevent the frame from being separated from the housing.

4. The display module as claimed in claim 3, wherein the first and second hooks are arranged in a direction parallel to the side of the frame.

5. The display module as claimed in claim 3, wherein the tails of the first hooks extend outwardly with respect to the first joining mechanism.

6. The display module as claimed in claim 5, wherein the tails of the second hooks extend inwardly with respect to the second joining mechanism.

7. The display module as claimed in claim 5, wherein the first joining mechanism further has a connecting portion connected between the two first hooks.

8. The display module as claimed in claim 7, wherein the first joining mechanism further has a hole surrounded by the connecting portion, the two first hooks, and the plate of the housing.

9. The display module as claimed in claim 5, wherein the first joining mechanism further has a curved concave surface formed between the two first hooks.

10. The display module as claimed in claim 1, wherein the first hook of the first joining mechanism and the second hook of the second joining mechanism are both in a shape of a golf driver head.
